(19) United States
(12) Patent Application Publication
(10) Pub. No.: US 2025/0364502 A1
(43) Pub. Date: Nov. 27, 2025

(54) MULTICOLOR MONOLITHIC LIGHT-EMITTING DIODE ARRAY

(71) Applicant: Lumileds LLC, San Jose, CA (US)

(72) Inventors: Grigoriy Basin, San Francisco, CA (US); Theodoros Mihopoulos, Mountain View, CA (US)

(73) Assignee: Lumileds LLC, San Jose, CA (US)

(21) Appl. No.: 18/671,166

(22) Filed: May 22, 2024

(51) Int. Cl. H01L 25/075; H01L 33/00; H01L 33/14; H01L 33/32; H01L 33/46; H01L 33/50; H01L 33/62

(52) U.S. Cl. CPC H01L 25/0753; H10H 20/01335; H10H 20/816; H10H 20/825; H10H 20/841; H10H 20/8513; H10H 20/857; H10H 20/034

(57) ABSTRACT

Described are multicolor monolithic light-emitting diode (LED) arrays comprising: multicolor pixels comprising a plurality of light emitting diode (LED) die including: a first set of LED die each of a first die height and configured to emit a first color light; a second set of LED die each of a second die height and configured to emit a second color light; a third set of LED die each of a third die height and configured to emit a third color light; and the first die height being substantially equal to the second die height and the third die height; and the plurality of LED die having a coplanar configuration and being spaced apart and retained by a reflective coating.

### TECHNICAL FIELD

Embodiments of the disclosure generally relate to light emitting devices and methods of manufacturing the same. More particularly, embodiments are directed to a multicolor monolithic light emitting diode (LED) array including die of differing colors, which are coplanar, having a configuration of a reflective mold retaining the LED die, e.g., a combination of red-green-blue (RGB) LED die.

### BACKGROUND

A light emitting diode (LED) is a semiconductor light source that emits visible light when current flows through it. LEDs combine a P-type semiconductor with an N-type semiconductor. LEDs commonly use a Ill-group compound semiconductor. A III-group compound semiconductor provides stable operation at a higher temperature than devices that use other semiconductors. The Ill-group compound is typically formed on a substrate, e.g., a growth substrate, formed of for example sapphire or silicon carbide (SiC).

Generally, when LED arrays including differing types of die are prepared, the differing types of die are attached to a support individually. Differing types of die may include different semiconductor-containing structures and different structural features that making handling arrays of the same challenging.

There is a need for making multicolor monolithic light emitting diode (LED) arrays in efficient and cost-effective ways.

### SUMMARY

Embodiments of the disclosure are directed to multicolor monolithic light-emitting diode (LED) arrays, and systems including the LED arrays, and methods of making and using the LED arrays.

In an aspect, a multicolor monolithic light-emitting diode (LED) array comprises: multicolor pixels comprising a plurality of light emitting diode (LED) die including: a first set of LED die each of a first die height and configured to emit a first color light; a second set of LED die each of a second die height and configured to emit a second color light; a third set of LED die each of a third die height and configured to emit a third color light; and the first die height being substantially equal to the second die height and the third die height; and the plurality of LED die having a coplanar configuration and being spaced apart and retained by a reflective coating.

Another aspect includes light-emitting diode (LED) systems comprising: any of the multicolor monolithic light-emitting diode (LED) arrays disclose herein attached to a device substrate, optionally wherein the device substrate includes a plurality of device contacts in a coplanar configuration, the device contacts corresponding respectively to the first, second, and third UBMs of the LED array; and a controller configured to control the plurality of pixels individually and/or in sets.

An additional aspect is a method for making a multicolor monolithic light-emitting diode (LED) array, which method comprises: assembling on a support in a spaced apart configuration a plurality of light emitting diode (LED) die including: a first set of LED die each of a first die height and configured to emit a first color; a second set of LED die each of a second die height and configured to emit a second color light; and a third set of LED die each of a third die height and configured to emit a third color light; disposing a reflective material on the plurality of LED die that retains the plurality of LED die in the spaced apart configuration; planarizing the reflective material such that the first die height is substantially equal to the second die height and the third die height and the plurality of LED die have a coplanar configuration; and removing the support thereby preparing the multicolor array.

Another aspect is a method for operating a display comprising: determining an image to present on the display; driving the plurality of pixels of any LED system herein to provide the image; and controlling individual and/or sets of the plurality of pixels.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements. The drawings are not to scale.

FIG. 1 illustrates a process flow diagram for a method according to one or more embodiments;

FIGS. 2-6 illustrate process flow diagrams for various sub-methods of FIG. 1 according to one or more embodiments;

FIGS. 7-8 illustrate cross-sectional views of different light emitting die;

FIGS. 9-14 illustrate cross-sectional views of a light emitting device (interim structure and/or array) after various operations in the manufacture according to one or more embodiments;

FIGS. 15-20 illustrate cross-sectional views of a light emitting device (interim structure and/or array) after various operations in the manufacture according to one or more embodiments;

FIGS. 21-26 illustrate cross-sectional views of a light emitting device (interim structure and/or array) after various operations in the manufacture according to one or more embodiments;

FIGS. 27-31 illustrate top plan views of various light emitting devices according to one or more embodiments; and

FIG. 32 shows a block diagram of an LED system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “monolithic light emitting diode (LED) array” refers to a multitude of LED die or chips rigidly mounted to a device substrate. Emitters are arranged in an X,Y addressable matrix and may have separately addressable connection. The spacing between light emitting areas can vary in size according to the application. In some embodiments, the spacing is in a range of from 30 μm to 500 μm in width, and all values and subranges therebetween, including 50 μm to 120 μm or 120 μm to 500 μm. The array sizes and shapes can vary to meet specific requirements.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

The term “wafer” and “substrate” will be used interchangeably in the instant disclosure. Thus, as used herein, a wafer serves as the substrate for the formation of the LED devices described herein. A growth or monolithic substrate is a substrate on which semiconductor layers are formed.

A device substrate is a substrate to which a LED chip or die or array is transferred and/or affixed after the semiconductor layers are formed. Exemplary device substrates are: circuit boards, tiles, metalized ceramics, thin film display backplane, CMOS backplane, CMOS microIC, and/or the like. These device substrates range in use from support or sub-mounts for individual LEDs or pixels to fully integrated electronics for displays and lighting applications and other suitable devices or systems.

As used herein, reference to the plurality of LED die being spaced apart and retained by a reflective coating means that an array of such LED die is self-supporting in that the array can be handled and processed without residing on a support. Such self-supporting arrays can be planarized and subsequently bonded and electrically coupled to a backplane, PCB, submount, and the like.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, LED fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Embodiments described herein provide a multicolor monolithic light-emitting diode (LED) array comprising multicolor pixels. The arrays include a plurality of light emitting diode (LED) die including: a first set of LED die each of a first die height and configured to emit a first color light; a second set of LED die each of a second die height and configured to emit a second color light; a third set of LED die each of a third die height and configured to emit a third color light. The first die height is substantially equal to the second die height and the third die height. The plurality of LED die have a coplanar configuration and are spaced apart and retained by a reflective coating.

High power LED packages are mostly manufactured by attaching individual LED die to a carrier by a solder process. In turn, a ceramic, metal core printed circuit board (MCPCB), or other carrier becomes part of a final package. Reference to “die” herein refers to a combination of a semiconductor-containing structure and corresponding under bump metallization(s) (UBM(s)). A semiconductor-containing structure is at least a stack of semiconductor layers, with or without a growth substrate, with or without internal bonding layers or other layers/features.

It can be desirable to include different types of die in an array. For example, combinations of vertical configurations and flip chip configurations allow for multicolor displays. Vertical configurations sometimes include wirebond pads and a bonding wire, which flip chip configurations do not. For example, AlInGaP die may be need to be wire bonded, and InGaN die are flip chip and do not need wire bonds. It would be beneficial to be able to handle different configurations of die within a single array to facilitate handling and manufacturing.

As to different colors, some die may include semiconductor-containing structures comprising a phosphide light emitting layer (e.g., AlInGaP) and other die may include semiconductor-containing structures comprising a nitride light emitting layer (e.g., GaN or InGaN), in which case there is a difference in semiconductor-containing structures height, which can lead to differences in die height.

Some applications need die of the same or substantially the same height and need to isolate light emitted from LED-to-LED by using the side coating materials.

For optical purposes a growth substrate such as sapphire on which a nitride light emitting layer (e.g., GaN) is grown is desired to be thin enough to maximize light output.

Selection of multiple die, therefore, presents varying structural requirements to achieve an array of LEDs of different colors: RGB on a tape, side coat them to prevent crosstalk, differing heights, but which are located in one plane and including both wire bonded and flip chip types with direct attach to a board.

Herein, the various requirements are accommodated by preparing arrays to solder by: attaching individual LED dies to a tape, adjust height by grinding sapphire and/or increasing the UBM heigh prior to placement on the tape, and protecting wirebond pad of vertical configuration die from the side coat material.

The tape can have a thermal release coating on the side which attached to the carrier, it is easy to remove it by curing for short time at the temperature which allows separating the thermally sensitive layer from the carrier and finally the full tape stack is removed from the back of the package.

Techniques herein therefore result in ways to construct arrays of different types of LEDs, e.g., different colors, differing materials, differing semiconductor-containing structure heights, which unite them together for future attachment to a final carrier/board. In one or more embodiments, techniques herein accommodate LEDs which have different structures and which should be located in one plane, prevent cross talk, and protect wire bond area on the die from side coat material.

Such monolithic arrays later can be later mounted to an appropriate printed circuit board (PCB) or other device substrate. In one or more embodiments, to control light cross talk between the LED, a thin layer of light absorbing material is inserted.

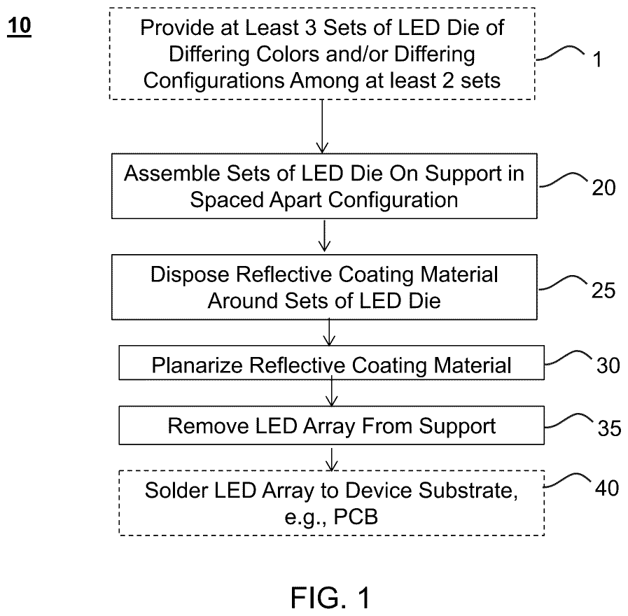

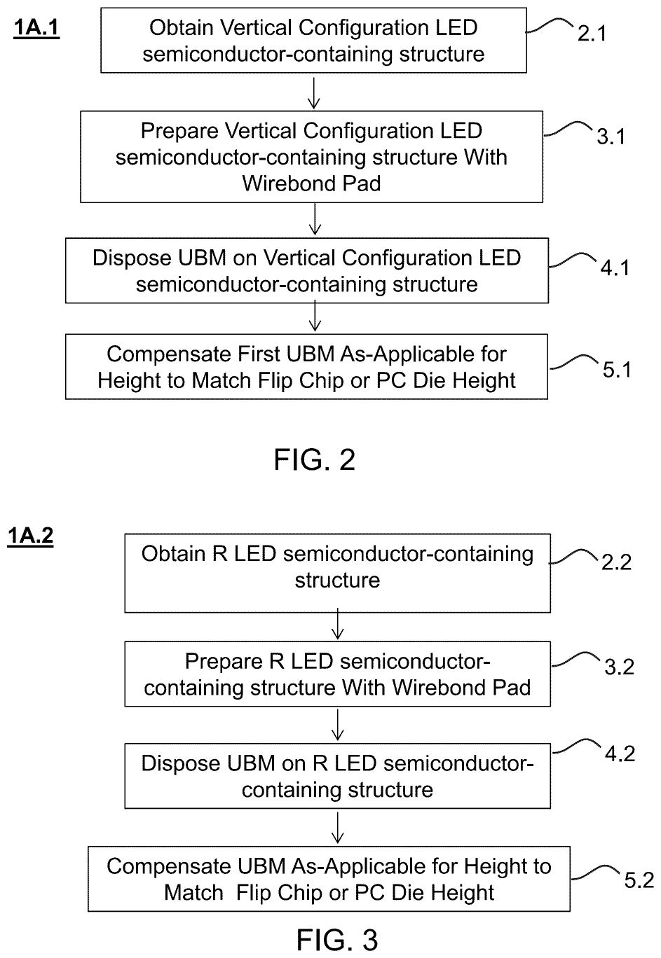

FIG. 1 depicts a flow diagram of a method 10 of manufacturing a light emitting device in accordance with one or more embodiments of the present disclosure. With reference to FIG. 1, in one or more embodiments, the method begins at operation 1 where at least three sets of LED die of differing colors and/or differing configurations among at least two sets are provided. As used in this specification and the appended claims, the term “provided” means that the LED die are made available for processing. FIG. 2-6 provide sub-methods in support of operation 1 of FIG. 1.

At operation 20, sets of the LED die are assembled on a support in a spaced apart configuration. In one or more embodiments, assembling including attaching or affixing the LED die to a support such as tape. A reflective coating material is disposed around the sets of LED die at operation 25 to prepare a first intermediate structure.

Optionally after operation 25, an opening in the reflective coating material is formed. Also optionally thereafter, a light absorbing material is deposited in the opening.

At operation 30, the first intermediate structure is planarized, including planarizing the reflective coating material and any light absorbing material when present. Depending on the application, UBMs are planarized during operation 30. Such planarizing is effective to open metal contacts. In one or more embodiments, planarizing the reflective coating material exposes backside surfaces of respective under bump metallizations (UBMs) of the first, second, and third sets of LED die. In one or more embodiments, there is planarizing of topside surfaces of the first, second, and third sets of LED die

At operation 35, the LED array is removed from the support. At operation 40, the LED array is soldered to device substrate such as a printed circuit board (PCB) or other substrate.

FIG. 2 depicts a flow diagram of a sub-method 1A.1 to prepare vertical configuration LED die, which is a portion of implementing operation 1 of FIG. 1 directed to providing at least three sets of LED die of differing colors and/or differing configurations among at least two sets. At operation 2.1, first vertical configuration LED semiconductor-containing structures are obtained. As used in this regard, the term “obtained” means that the LED semiconductor-containing structures are placed into a position or environment for further processing. At operation 3.1, the vertical configuration LED semiconductor-containing structures are prepared with respective wirebond pads. At operation 4.1, first underbump metallizations (UBMs) are attached to the first vertical configuration LED semiconductor-containing structures. At operation 5.1, as-applicable, the first UBMs are planarized or otherwise sized to prepare vertical configuration LED die, which compensates for any height differences relative to flip chip or phosphor converted (PC) die to be included in the same array.

FIG. 3 depicts a flow diagram of a sub-method 1A.2, which is more detailed than the sub-method 1A.1 of FIG. 2. The sub-method 1A.2 is to prepare red LED die, which is another portion of implementing operation 1 of FIG. 1. Red LED die generally include a phosphide light emitting layer, for example AlInGaP. At operation 2.2, red LED semiconductor-containing structures are obtained. At operation 3.2, the red LED semiconductor-containing structures are prepared with respective wirebond pads. At operation 4.2, first red underbump metallizations (UBMs) are attached to the red LED semiconductor-containing structures. At operation 5.2, as-applicable, the first red UBMs are planarized or otherwise sized to prepare red LED die, which compensates for any height differences relative to flip chip or phosphor converted (PC) die to be included in the same array.

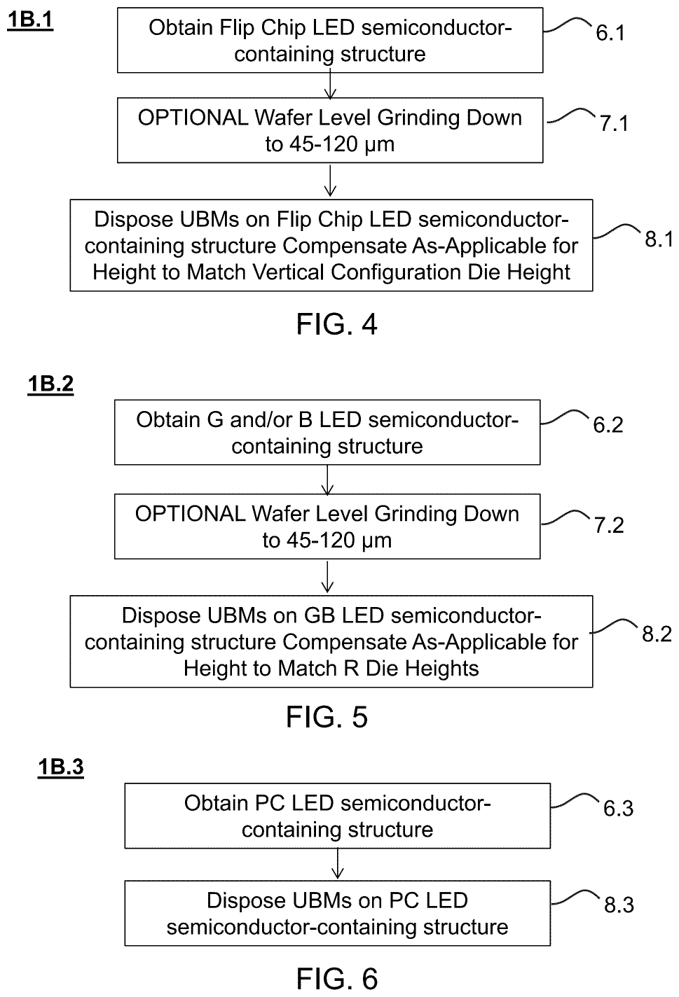

FIG. 4 depicts a flow diagram of a sub-method 1B.1 to prepare flip chip configuration LED die, which is another portion of implementing operation 1 of FIG. 1 directed to providing at least three sets of LED die of differing colors and/or differing configurations among at least two sets. At operation 6.1, first flip chip LED semiconductor-containing structures are obtained. At optional operation 7.1, thinning of the flip chip LED semiconductor-containing structures is conducted at the wafer level to achieve a desired thickness, for example, a thickness of 45 to 120 micrometers, including all values and ranges therein, including 60 to 80 micrometers. As used herein, includes mechanical-chemical lapping or polishing, or wet or dry etching, with a preferred method being grinding. At operation 8.1, flip chip underbump metallizations (UBMs) are attached to the flip chip LED semiconductor-containing structures. As-applicable, the flip chip UBMs are planarized or otherwise sized to prepare flip chip LED die, which compensates for any height differences relative to vertical configuration die to be included in the same array.

FIG. 5 depicts a flow diagram of a sub-method 1B.2, which is more detailed than the sub-method 1B.1 of FIG. 4. The sub-method 1B.2 is to prepare green and/or blue LED die, which is another portion of implementing operation 1 of FIG. 1. Green and blue LED die generally include a nitride light emitting layer, for example GaN or InGaN. At operation 6.2, green and/or blue LED semiconductor-containing structures are obtained. At optional operation 7.2, grinding of the green and/or blue LED semiconductor-containing structures is conducted at the wafer level to achieve a desired thickness, for example, a thickness of 45 to 120 micrometers, including 60 to 80 micrometers. At operation 8.2, green and/or blue underbump metallizations (UBMs) are attached respectively to the green and/or blue LED semiconductor-containing structures. As-applicable, the green and/or blue UBMs are planarized or otherwise sized to prepare green and/or blue LED die, which compensates for any height differences relative to red LED die to be included in the same array.

FIG. 6 depicts a flow diagram of a sub-method 1B.3, which is more detailed than the sub-method 1B.1 of FIG. 4. The sub-method 1B.3 is to prepare phosphor converted (PC) LED die, which is another portion of implementing operation 1 of FIG. 1. PC-LED die generally include a nitride light emitting layer, for example GaN or InGaN and a phosphor layer. At operation 6.3, PC-LED semiconductor-containing structures are obtained. At operation 8.3, PC underbump metallizations (UBMs) are attached respectively to the PC-LED semiconductor-containing structures.

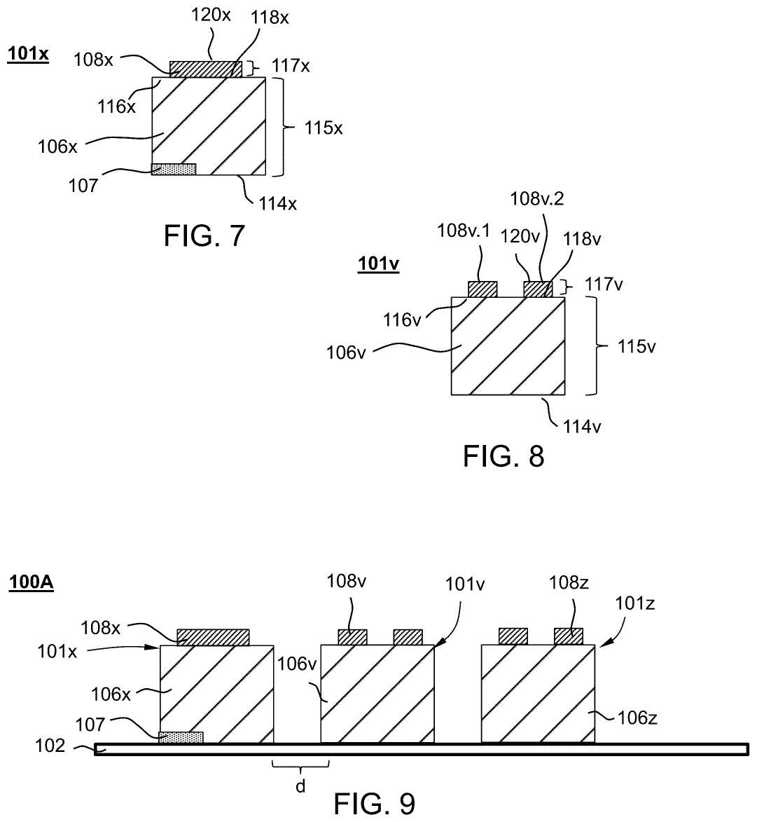

FIGS. 7 and 8 illustrate cross-sectional views of different light emitting die 101x and 101v, respectively.

In FIG. 7, die 101x is representative of a vertical configuration LED die, comprising: (first) semiconductor-containing structure 106x and (first) underbump metallization (UBM) 108x. The semiconductor-containing structure 106x has a (first) semiconductor-containing structure height 115x spanning from a (first) growth surface 114x to a (first) deposition surface 116x. The underbump metallization (UBM) 108x has a (first) UBM height 117x spanning from a (first) UBM attachment surface 118x to a (first) UBM device surface 120x. The first UBM device surface 120x of the first UBM 108x is disposed on the first deposition surface 116x of the first semiconductor-containing structure 106x. In one or more embodiments, the vertical configuration LED die include a phosphide light emitting layer (e.g., AlInGaP). In one or more embodiments, the vertical configuration LED die are effective to emit red light. In one or more embodiments, the vertical configuration includes a silicon substrate.

A wirebond pad 107 is affixed to the semiconductor-containing structure 106x. The wirebond pad 107 is typically light absorbing and generally only slightly larger in diameter than a wire being attached thereto to connect to a substrate, e.g., a device substrate. The wirebond pad 107 can extend somewhat over a top interior of the semiconductor-containing structure 106x to help spread current. Current spreading can be helped with the use of a transparent conducting oxide (TCO, such as ITO) that is electrically coupled to the wirebond pad 107.

In FIG. 8, die 101v is representative of a flip chip LED die, comprising: (second) semiconductor-containing structure 106v and (second) underbump metallizations (UBMs) 108v.1 and 108v.2. FIG. 8 is analogously representative of die 101z of FIGS. 9-14. The semiconductor-containing structure 106v has a (second) semiconductor-containing structure height 115v spanning from a (second) growth surface 114v to a (second) deposition surface 116v. The underbump metallizations (UBMs) 108v.1 and 108v.2 each have a (second) UBM height 117v spanning from respective (second) UBM attachment surface 118x to (second) UBM device surface 120v. The second UBM device surfaces 120v of the respective second UBMs 108v.1 and 108v.2 are disposed on the second deposition surface 116v of the second semiconductor-containing structure 106v. In one or more embodiments, the flip chip LED die include a nitride light emitting layer (e.g., GaN or InGaN). In one or more embodiments, the flip chip LED die are effective to emit blue or green light. In one or more embodiments, the flip chip configuration includes a sapphire (growth) substrate.

Within the semiconductor-containing structures 106x and 106v (and analogously 106z), according to one or more embodiments, a transparent substrate may be present, comprising any suitable substrate known to the skilled artisan, on which semiconductor epitaxial layers are grown. In one or more embodiments, the transparent substrate comprises one or more of sapphire, silicon carbide, silicon (Si), quartz, magnesium oxide (MgO), zinc oxide (ZnO), spinel, and the like. In one or more embodiments, the transparent substrate is not patterned prior to the growth of an epi-layer. Thus, in some embodiments, the transparent substrate is not patterned and can be characterized as flat or substantially flat. In other embodiments, the transparent substrate is patterned, e.g., patterned sapphire substrate (PSS).

In some embodiments, the transparent substrate can support an epitaxially grown or deposited semiconductor N-layer. A semiconductor p-layer can then be sequentially grown or deposited on the N-layer, forming an active region at the junction between layers. Semiconductor materials capable of forming high-brightness light emitting devices can include, but are not limited to, Group III-V semiconductors, particularly binary, ternary, and quaternary alloys of gallium, aluminum, indium, and nitrogen, also referred to as III-V nitride materials. In some embodiments, the III-nitride material comprises one or more of gallium (Ga), aluminum (Al), and indium (In). Thus, in some embodiments, the semiconductor layer comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more specific embodiments, the semiconductor layer comprises gallium nitride and is an n-type layer.

It will be appreciated by one of skill in the art that the transparent substrate may include one or more material layers (e.g., Ill-nitride, and the like), vias, and the like thereon. In one or more embodiments, the substrate may include semiconductor layers including an N-type layer, an active layer, and a P-type layer that is capable of emitting light when electrically powered.

Embodiments of arrays herein include at least three sets of LED die of differing colors and/or differing configurations among at least two sets. In one or more embodiments, a first set of LED die comprise a vertical configuration, and the second set of LED die comprise a flip chip configuration, and the third set of LED die comprise either a vertical configuration or a flip chip configuration. In a detailed embodiment, the vertical configuration comprises a vertical thin film (VTF) configuration. In a detailed embodiment, the flip chip configuration comprises a thin film flip chip configuration (TFFC). In a detailed embodiment, the vertical configuration comprises a vertical thin film (VTF) configuration and the flip chip configuration comprises a thin film flip chip configuration (TFFC). In one or more embodiments, a first die height, a second die height, and a third die height of the LED arrays have dimensions within 10 micrometers of each other, and more preferred within 5 micrometers of each other.

FIGS. 9 to 14 illustrate views of LED intermediate structures 100A to 100D during preparation of an LED device 150A or 150B following the process flow illustrated for method 10 of FIG. 1, method 1A.1 of FIG. 2, and method 1B.1 of FIG. 4. FIGS. 9 to 14 are cross-section views of the light emitting device. In FIGS. 9 to 14, the LED semiconductor-containing structures are the same height or essentially the same height, in which case no additional operations are needed to compensate UBMs for height differentials. For illustration purposes, a first set of LED die comprise a vertical configuration 101x, and the second and third sets of LED die 101v and 101z comprise a flip chip configuration.

Assembling the sets of the LED die on a support at operation 20 of FIG. 1 yields intermediate LED structure 100A of FIG. 9. In one or more embodiments, vertical configuration LED semiconductor-containing structure 106x and flip chip LED semiconductor-containing structures 106v and 106z are obtained at operation 2.1 and processed as-applicable in accordance with FIG. 2. Vertical configuration LED die 101x (see also FIG. 7) and the flip chip LED die 101v and 101z (see also FIG. 8) are accordingly provided at operation 1. In one or more embodiments, the respective LED die include: at least one electrical contact, otherwise known as underbump metallizations (UBMs), 108x, 108v, 108z; and a semiconductor-containing structure 106x, 106v, 106z. The semiconductor-containing structure 106x of the vertical configuration LED die 101x further includes the wirebond pad 107.

The LED die 101x, 101v, and 101z are assembled onto a surface of the support 102 by way of their respective growth surfaces (e.g., 114x of FIG. 7 and 114 v of FIG. 8) at a distance “d” between adjacent semiconductor-containing structures 106x, 106v, 106z. In one or more embodiments, distance, d, is in a range of from 10 μm to 500 μm. In other embodiments, the LED semiconductor-containing structures 106x, 106v, 106z are spaced at least about 120 μm apart from an adjacent LED semiconductor-containing structure. It is understood that an entire assembly of the various LED die 101x, 101v, and 101z is done according to end-applications, and that the figures herein are not limiting as to which LED die are next to each other and in how many quantities.

In one or more embodiments of the LED die, the electrical contacts or UBMs 108x, 108v, 108z are on the respective deposition surfaces (e.g., 116x of FIG. 7 and 116v of FIG. 8), or top surface, of the semiconductor-containing structures 106x, 106v, and 106z. The UBMs 108x, 108v, 108z may comprise any suitable contact known to the skilled artisan. For example, in some embodiments, the UBM 108x, 108v, 108z may comprise one or more of a p-type contact or an n-type contact. In some embodiments, the UBMs 108x, 108v, 108z include a metal selected from one or more of copper (Cu), nickel (Ni), aluminum (Al), and gold (Au). In one or more embodiments, the UBMs herein, e.g., 108x, 108v, 108z are plated with gold (Au) through an immersion process to form gold plated electrical contacts. Gold (Au) plating is done by electroless nickel immersion gold (ENIG). It comprises electroless nickel plating, which is covered with a thin layer of immersion gold. In immersion gold, the gold layer is generated on the nickel layer through displacement. It continues until the generated gold layer is covered with nickel. This is why gold layer is very thin. This layer protects nickel from oxidation.

In one or more embodiments, the support 102 comprises any suitable support material. In one or more embodiments, the support 102 is removable. In one or more specific embodiments, the support 102 is a carrier tape. The tape can be dual side coated, such as one side having a pressure sensitive adhesive and another has a thermal release or UV sensitive adhesive which allows, when exposed to UV light, to release form the solid substrate.

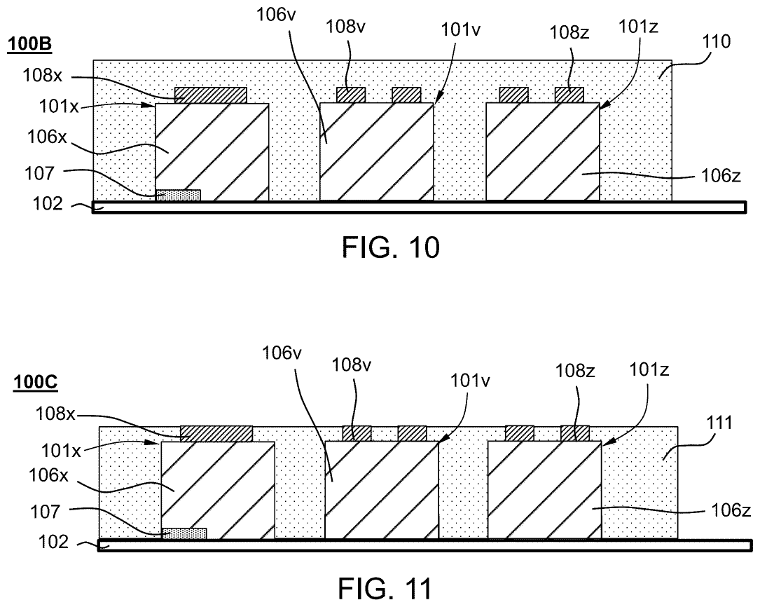

Turning to FIG. 10 and intermediate structure 100B, at operation 25 of method 10, a reflective material 110 is disposed around sets of the LED die of the intermediate structure 100A. In one or more embodiments, the reflective material 110 is molded around the sets of the LED die. The reflective material 110 interacts with all surfaces of the LED die 101x, 101v, and 101z except for the surfaces (respective growth surfaces, e.g., 114x of FIG. 7 and 114 v of FIG. 8) that are on the support 102. With respect to the vertical configuration LED die 101x, a surface of the wirebond pad 107 facing/on the support 102 is protected from the reflective material 110.

In one or more embodiments, the reflective material 110 is highly reflective having a reflectance in a range of from 80% to 99%, including all values and subranges therebetween, including in a range of from 80% to 98%, or in a range of from 90% to 98%, or in a range of from 91% to 97%, or in a range of from 92% to 96%, or in a range of from 93% to 95%.

The reflective material 110 may comprise any suitable material known to the skilled artisan. In one or more embodiments, the reflective material is selected from one or more of silicone, titanium oxide (TiO₂), zirconium oxide (ZrO₂), aluminum oxide (Al₂O₃), or other metal oxides.

In some embodiments, the reflective material 110 includes a channel in which a thin vertical layer of light absorbing material resides. Without intending to be bound by theory, it is thought that the presence of the light absorbing material in the reflective material 110 facilitates reduced optical crosstalk between the LED die. The channel may extends into the reflective material to a desired depth towards the support 102. In some instances, the channel extends completely through the reflective material to the support 102. The channel may be formed by any suitable means known to the skilled artisan. In one or more embodiments, the reflective material 110 is sawed with a thin blade to create the channel between the LED die. Such opening may has a width, w, in a range of from 1 μm to 30 μm, or in a range of from 5 μm to 25 μm, or in a range of from 10 μm to 25 μm. The light absorbing material may comprise any suitable material known to the skilled artisan, for example, one or more of silicone, carbon, and a metal material.

Turning to FIG. 11 and intermediate structure 100C, at operation 30 of method 10, the reflective material 110 is planarized or ground to remove a portion thereof from a top surface of the intermediate structure 100B. The reflective material 110 may be removed by any suitable means including, but not limited to chemical mechanical planarization (CMP) and grinding. Upon planarizing, the reflective material 110 yields a reflective coating 111, which may have any suitable thickness. In one or more embodiments, the reflective coating 111 has a thickness in a range of from 40 μm to 60 μm.

In one or more embodiments, the reflective coating 111 serves not only to reflect light, but also serves as a structure element of an array (e.g., 113 of FIG. 13) by holding the LED die 101x, 101v, and 101z of the array together. Thus, in one or more embodiments, the LED die 101x, 101v, and 101z in the light-emitting diode (LED) array 113 are fixed in place by the reflective coating 111.

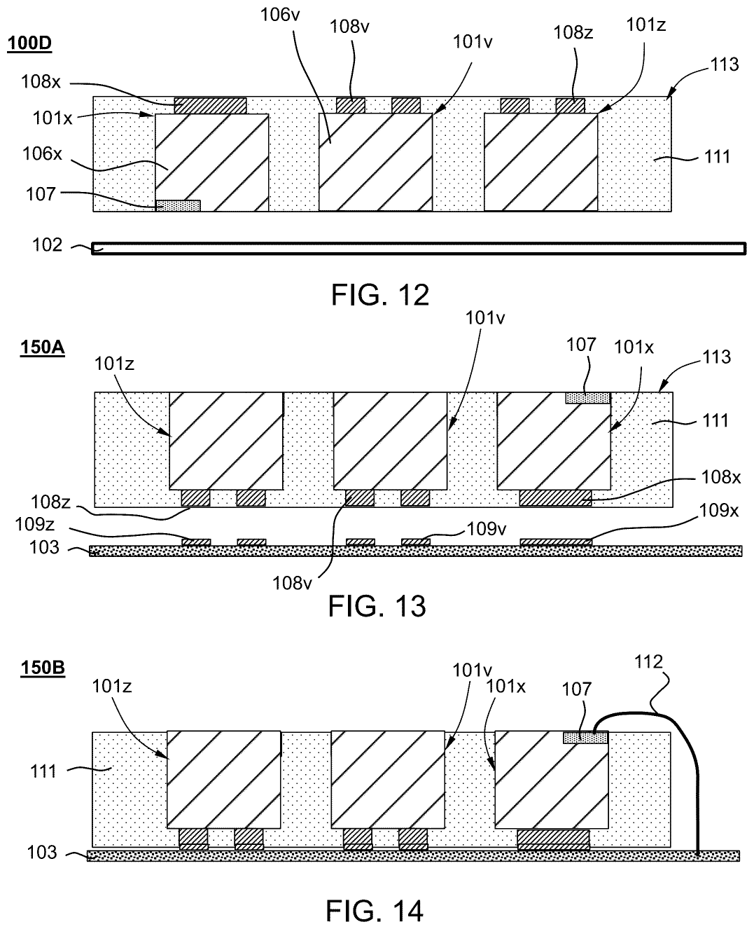

At operation 35, as illustrated in FIG. 12 by intermediate structure/array 100D, array 113 is removed from the support 102.

With reference to FIG. 13, intermediate structure 150A comprises the array 113, which is flipped and placed in proximity to a device substrate 103, for example a printed circuit board (PCB) or other suitable substrate for inclusion in a final system or device. The device substrate 103 has device contacts 109z, 109v, 109x that correspond to respective UBMs 108z, 108v, 108x. The device contacts 109z, 109v, 109x are in a coplanar configuration relative to each other.

At operation 40, the array 113 of FIG. 13 is attached to the device substrate 103 to prepare LED device 150B of FIG. 14. The device contacts 109z, 109v, 109x and respective UBMs 108z, 108v, 108x are bonded or otherwise soldered. A bonding wire 112 electrically connected to the device substrate 103 is affixed to the wirebond pad 107 of each of the vertical configuration LED die 101x.

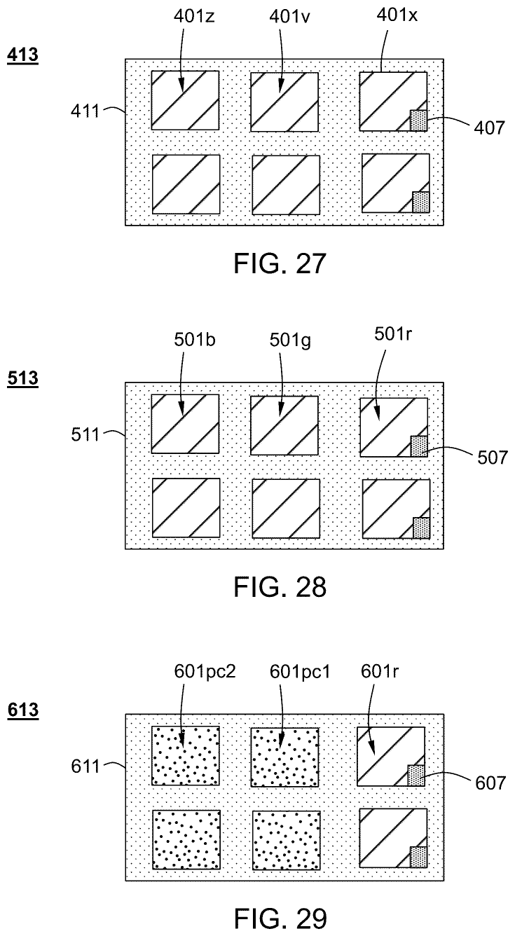

FIG. 27 is a top plan view of array 113 of FIG. 13 prepared according to the method 10 of FIG. 1. As shown in FIG. 27, array 413 includes the vertical configuration LED die 401x including wirebond pad 407 and the flip chip die 401v, 401z, all of the die being held in place by the reflective coating material 411.

In one or more embodiments, the LED die 401x, 401v, and 401z are configured to emit different colors. In embodiments, the die 401x represents a first set of LED die each of a first die height and configured to emit a first color light, the die 401v represents a second set of LED die each of a second die height and configured to emit a second color light; and the die 401z represents a third set of LED die each of a third die height and configured to emit a third color light. As shown in cross-section of FIGS. 9-14, the plurality of LED die have a coplanar configuration and are spaced apart and retained by the reflective coating. In the embodiment of FIG. 27, the first set of LED die comprise a vertical configuration, and the second and third sets of LED die comprise a flip chip configuration.

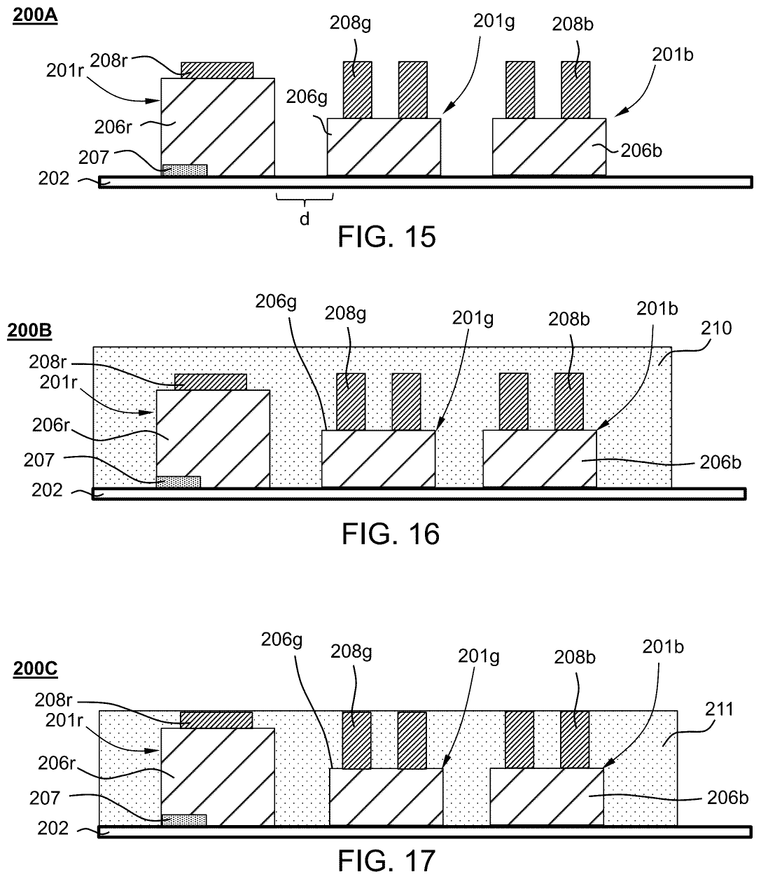

FIGS. 15 to 20 illustrate views of LED intermediate structures 200A to 200D during preparation of an LED device 250A or 250B following the process flow illustrated for method 10 of FIG. 1, method 1A.2 of FIG. 3, and method 1B.2 of FIG. 5. FIGS. 15 to 20 are cross-section views of the light emitting device. In FIGS. 15 to 20, the LED semiconductor-containing structures include two differing heights among the three, in which case an additional operation is needed to compensate UBMs for height differentials. In one or more embodiments, two of the semiconductor-containing structures have essentially the same height, and are shorter in height than the other semiconductor-containing structure.

Assembling the sets of the LED die on a support at operation 20 of FIG. 1 yields intermediate LED structure 200A of FIG. 15. In one or more embodiments, red LED semiconductor-containing structure 206r is obtained at operation 2.2; green LED semiconductor-containing structure 206g and blue LED semiconductor-containing structure 206b are obtained at operation 6.2. The red LED semiconductor-containing structure 206r is processed as-applicable in accordance with FIG. 3. The green LED semiconductor-containing structure 206g and blue LED semiconductor-containing structure 206b are processed as-applicable in accordance with FIG. 5, including compensating for a difference in height of the semiconductor-containing structures compared to the red LED semiconductor-containing structure. In one or more embodiments, the respective LED die include: at least one electrical contact, otherwise known as underbump metallizations (UBMs), 208r, 208g, 208b; and a semiconductor-containing structure 206r, 206g, 206b. The semiconductor-containing structure 206r of the red LED die 201r further includes wirebond pad 207.

The LED die 201r, 201g, and 201b are assembled onto a surface of the support 202 by way of their respective growth surfaces (e.g., 114x of FIG. 7 and 114 v of FIG. 8) at a distance “d” between adjacent semiconductor-containing structures 206r, 206g, 206b. In one or more embodiments, distance, d, is in a range of from 10 μm to 500 μm. In other embodiments, the semiconductor-containing structure 206r, 206g, 206b are spaced at least about 120 μm apart from an adjacent LED semiconductor-containing structure. It is understood that an entire assembly of the various LED die 201r, 201g, and 201b is done according to end-applications, and that the figures herein are not limiting as to which LED die are next to each other and in how many quantities.

A first set of LED die represented by 201r include a first semiconductor-containing structure 206r of a first semiconductor height and a first under bump metallization (UBM) 208r of a first UBM height. A second set of LED die 201g each include a second semiconductor-containing structure 206g of a second semiconductor height and a second under bump metallization (UBM) 208r of a second UBM height. A third set of LED die 201b each include a third semiconductor-containing structure 206b of a third semiconductor height and a third under bump metallization (UBM) 208b of a third UBM height. In this embodiment, the first semiconductor-containing structure 206r height is greater than the second semiconductor-containing structure 206g height and the third semiconductor-containing structure 206b height, and the first UBM height is less than the second and third UBM heights.

In one or more embodiments of the LED die 201r, 201g, and 201b, the electrical contacts or UBMs 208r, 208g, 208b are on the respective deposition surfaces (e.g., 116x of FIG. 7 and 116v of FIG. 8), or top surface, of the semiconductor-containing structures 206r, 206g, and 206b. The UBMs 208r, 208g, 208b may comprise any suitable contact known to the skilled artisan analogously to UBMs 108x, 108v, 108z.

In accordance with operation 8.2 of FIG. 5, the UBMs 208g of the green LED die 201g and UBMs 208b of the blue LED die 201b are prepared to compensate for the semiconductor-containing structure 206r of the red LED die 201r being taller than the semiconductor-containing structure 206g of the green LED die 201g and the semiconductor-containing structure 206b of the blue LED die 201b.

The support 202 comprises any suitable support material analogously to support 102.

Turning to FIG. 16 and intermediate structure 200B, at operation 25 of method 10, a reflective material 210 is disposed around sets of the LED die of the intermediate structure 200A. In one or more embodiments, the reflective material 210 is analogous to the reflective material 110 in deposition techniques, materials, and characterization. The reflective material 210 interacts with all surfaces of the LED die 201r, 201g, and 201b except for the surfaces (respective growth surfaces, e.g., 114x of FIG. 7 and 114 v of FIG. 8) that are on the support 202. With respect to the red LED die 201r, a surface of the wirebond pad 207 facing/on the support 202 is protected from the reflective material 210.

Turning to FIG. 17 and intermediate structure 200C, at operation 30 of method 10, the reflective material 210 is planarized or ground to remove a portion thereof from a top surface of the intermediate structure 200B. The reflective material 210 may be removed by any suitable means including, but not limited to chemical mechanical planarization (CMP) and grinding. Upon planarizing, the reflective material 210 yields a reflective coating 211, which may have any suitable thickness. In one or more embodiments, the reflective coating 211 has a thickness in a range of from 40 μm to 60 μm.

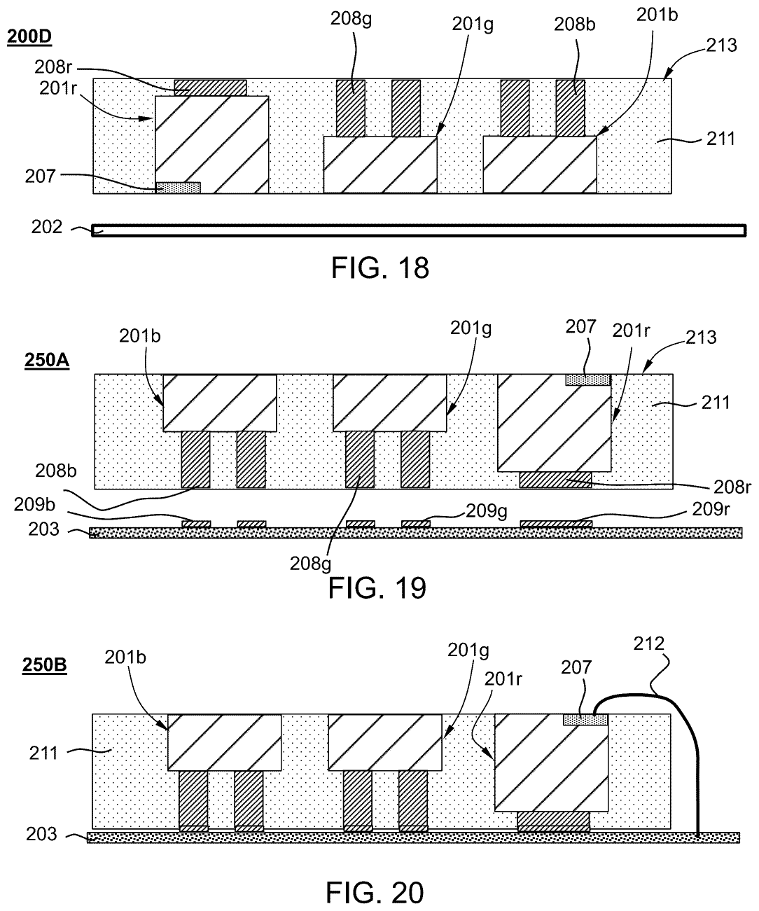

In one or more embodiments, the reflective coating 211 serves not only to reflect light, but also serves as a structure element of an array (e.g., 213 of FIG. 18) by holding the LED die 201r, 201g, and 201b of the array together. Thus, in one or more embodiments, the LED die 201r, 201g, and 201b in the light-emitting diode (LED) array 213 are fixed in place by the reflective coating 211.

At operation 35, as illustrated in FIG. 18 by intermediate structure/array 200D, array 213 is removed from the support 202.

With reference to FIG. 19, intermediate structure 250A comprises the array 213, which is flipped and placed in proximity to a device substrate 203, for example a printed circuit board (PCB) or other suitable substrate for inclusion in a final system or device. The device substrate 203 has device contacts 209b, 209g, 209r that correspond to respective UBMs 208b, 208g, 208r. The device contacts 209b, 209g, 209r are in a coplanar configuration relative to each other.

At operation 40, the array 213 of FIG. 19 is attached to the device substrate 203 to prepare LED device 250B of FIG. 20. The device contacts 209b, 209g, 209r and respective UBMs 208b, 208g, 208r are bonded or otherwise soldered. A bonding wire 212 electrically connected to the device substrate 203 is affixed to the wirebond pad 207 of each of the red LED die 201r.

FIG. 28 is a top plan view of array 213 of FIG. 19 prepared according to method 10 of FIG. 1 in conjunction with the specific sub-methods 1A.2 and 1B.2 of FIGS. 3 and 5. As shown in FIG. 28, array 513 includes red LED die 501r including wirebond pad 507, green LED die 501g, and blue LED die 501b, all of the die being held in place by reflective coating material 511.

In one or more embodiments, the LED die 501r, 501g, and 501b are configured to emit different colors, namely red, green, and blue respectively. In embodiments, the die 501r represents a first set of LED die each of a first die height and configured to emit a red color light, the die 501g represents a second set of LED die each of a second die height and configured to emit a green color light; and the die 501b represents a third set of LED die each of a third die height and configured to emit a blue color light. As shown in cross-section of FIGS. 15-20, the plurality of LED die have a coplanar configuration and are spaced apart and retained by the reflective coating. In the embodiment of FIG. 28, the first set of LED die comprise a vertical configuration, and the second and third sets of LED die comprise a flip chip configuration.

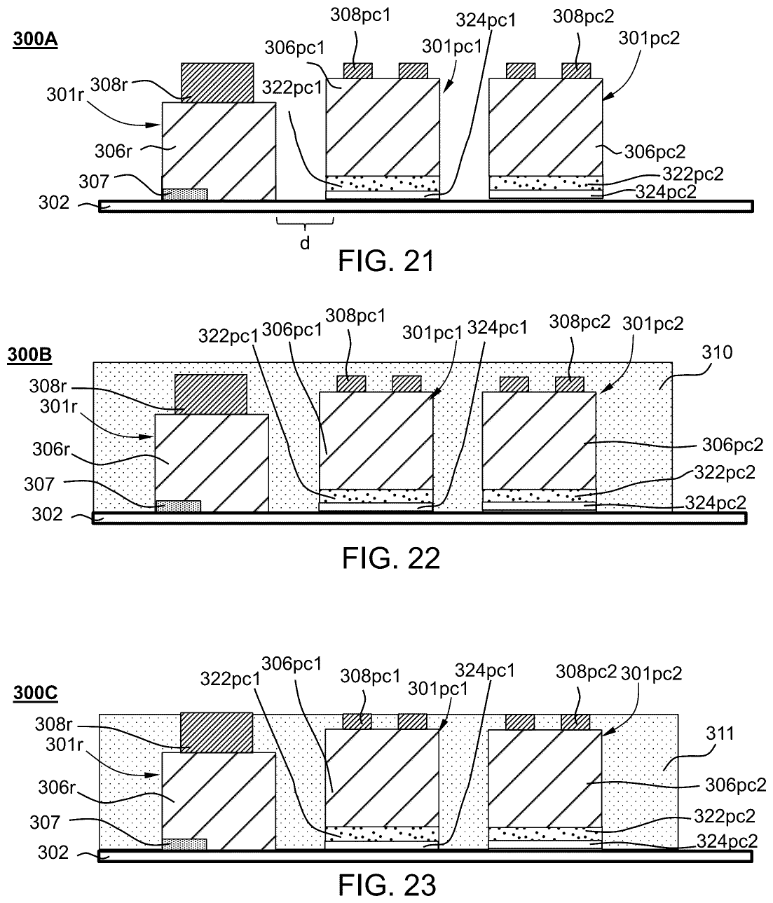

FIGS. 21 to 26 illustrate views of LED intermediate structures 300A to 300D during preparation of an LED device 350A or 350B following the process flow illustrated for method 10 of FIG. 1, method 1A.2 of FIG. 3, and method 1B.3 of FIG. 6. FIGS. 21 to 26 are cross-section views of the light emitting device. In FIGS. 21 to 26, phosphor-converted PC-LED semiconductor-containing structures of two of the sets of LED die have differing height as compared to the semiconductor-containing structure of the third set of LED die, in which case an additional operation is needed to compensate UBMs for height differentials. For illustration purposes, a first set of LED die comprise a vertical configuration 301r, and the second and third sets of LED die 301pc1 and 301pc2 are phosphor-converted and comprise a flip chip configuration. In this embodiment, two PC-LED die are illustrated, it is understood that one PC-LED die could be used in conjunction with two LED die (no phosphor conversion) of the same or differing height semiconductor-containing structures.

Assembling the sets of the LED die on a support at operation 20 of FIG. 1 yields intermediate LED structure 300A of FIG. 21. In one or more embodiments, red LED semiconductor-containing structure 306r is obtained at operation 2.2; first phosphor-converted PC-LED semiconductor-containing structure 306pc1 and second phosphor-converted PC-LED semiconductor-containing structure 306pc2 206b are obtained at operation 6.3. The red LED semiconductor-containing structure 306r is processed as-applicable in accordance with FIG. 3. The red LED semiconductor-containing structure 306r is processed as-applicable in accordance with FIG. 3, including compensating for a difference in height of the semiconductor-containing structures compared to PC-LED semiconductor-containing structures 306pc1 and 306pc2. In one or more embodiments, red LED die 301r include: at least one electrical contact, otherwise known as underbump metallizations (UBMs), 308r, a semiconductor-containing structure 306r, and the semiconductor-containing structure 306r further includes wirebond pad 307. In one or more embodiments, first and second PC-LED die 301pc1 and 301pc2 include respectively: at least one, preferably two electrical contacts, otherwise known as underbump metallizations (UBMs), 308pc1, 308pc2; a semiconductor-containing structure 306pc1, 306pc1; a wavelength converting material 322pc1, 322pc2; and optionally further a transparent cover layer 324pc1, 324pc2 on the wavelength converting material 322pc1, 322pc2.

In some embodiments, the wavelength converting material 322pc1, 322pc2 is on an opposing surface of the semiconductor-containing structure 306pc1, 306pc2 from the UBMs 308pc1, 308pc2. The wavelength converting material 322pc1, 322pc2 absorbs energy, converting an entering wavelength to a lower-energy higher wavelength, and scatter light. The wavelength converting material 322pc1, 322pc2 may comprise any suitable material known to the skilled artisan. In one or more embodiments, the wavelength converting material 322pc1, 322pc2 comprises phosphor. As used herein, the term “phosphor” refers to a solid material which emits visible light when exposed to radiation from a deep blue, ultra-violet, or electron beam source. Through careful tuning of the phosphor composition and structure, the spectral content of the emitted light can be tailored to meet certain performance criteria. In some embodiments, the phosphor is selected from a ceramic phosphor plate or phosphor in silicone.

The LED die 301r, 301pc1, and 301pc2 are assembled onto a surface of the support 302 by way of their respective growth surfaces (e.g., 114x of FIG. 7 and 114 v of FIG. 8) at a distance “d” between adjacent semiconductor-containing structures 306r, 306pc1, 306pc2. In one or more embodiments, distance, d, is in a range of from 10 μm to 500 μm. In other embodiments, the LED semiconductor-containing structures 306r, 306pc1, 306pc2 are spaced at least about 120 μm apart from an adjacent LED semiconductor-containing structure. It is understood that an entire assembly of the various LED die 301r, 301pc1, and 301pc2 is done according to end-applications, and that the figures herein are not limiting as to which LED die are next to each other and in how many quantities.

In one or more embodiments of the LED die 301r, 301pc1, and 301pc2, the electrical contacts or UBMs 308r, 308pc1, 308pc2 are on the respective deposition surfaces (e.g., 116x of FIG. 7 and 116v of FIG. 8), or top surface, of the semiconductor-containing structures 306r, 306pc1, and 306pc2. The UBMs 308r, 308pc1, 308pc2 may comprise any suitable contact known to the skilled artisan analogously to UBMs 108x, 108v, 108z.

In accordance with operation 5.2 of FIG. 3, the UBM 308r of the red LED die 301r is prepared to compensate for the semiconductor-containing structure 306r of the red LED die 301r being shorter than the semiconductor-containing structures 306pc1 and 306pc2 of the PC-LED 301pc1 and 301pc2 due to the presence of the wavelength converting material 322pc1, 322pc2 and optional transparent cover layer 324pc1, 324pc2.

The support 302 comprises any suitable support material analogously to support 102.

Turning to FIG. 22 and intermediate structure 300B, at operation 25 of method 10, a reflective material 310 is disposed around sets of the LED die of the intermediate structure 300A. In one or more embodiments, the reflective material 310 is analogous to the reflective material 110 in deposition techniques, materials, and characterization. The reflective material 310 interacts with all surfaces of the LED die 301r, 301pc1, and 301pc2 except for the surfaces (respective growth surfaces, e.g., 114x of FIG. 7 and 114 v of FIG. 8) that are on the support 302. With respect to the red LED die 301r, a surface of the wirebond pad 307 facing/on the support 302 is protected from the reflective material 310.

Turning to FIG. 23 and intermediate structure 200C, at operation 30 of method 10, the reflective material 310 is planarized or ground to remove a portion thereof from a top surface of the intermediate structure 300B. The reflective material 310 may be removed by any suitable means including, but not limited to chemical mechanical planarization (CMP) and grinding. Upon planarizing, the reflective material 310 yields a reflective coating 311, which may have any suitable thickness. In one or more embodiments, the reflective coating 311 has a thickness in a range of from 40 μm to 60 μm.

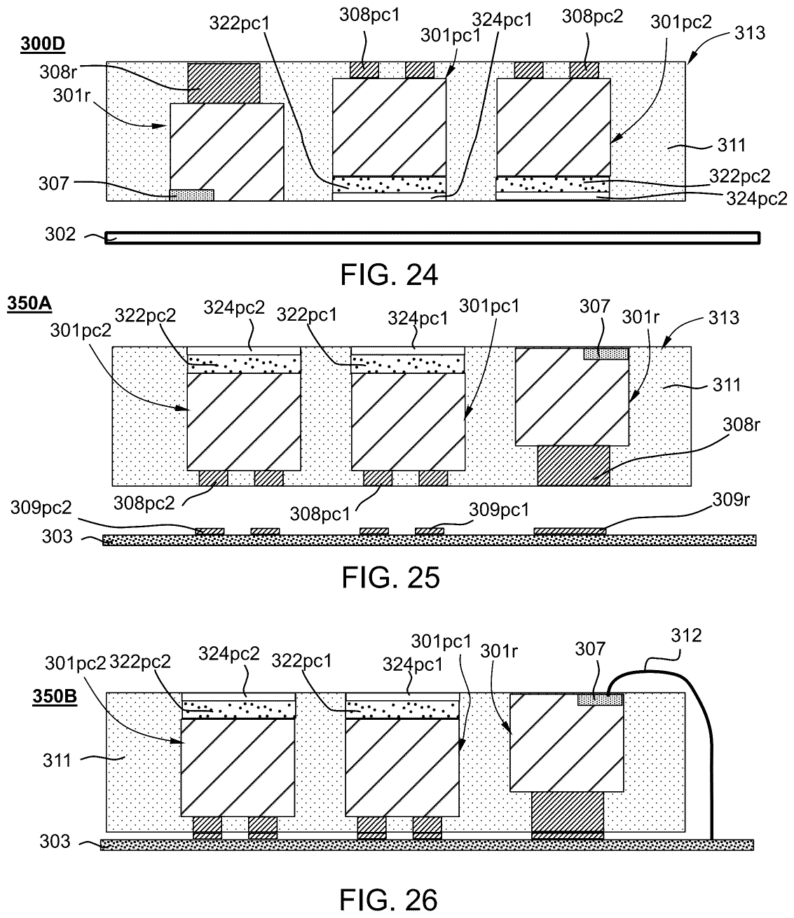

In one or more embodiments, the reflective coating 311 serves not only to reflect light, but also serves as a structure element of an array (e.g., 313 of FIG. 24 or 25) by holding the LED die 301r, 301pc1, and 301pc2 of the array together. Thus, in one or more embodiments, the LED die 301r, 301pc1, and 301pc2 in the light-emitting diode (LED) array 313 are fixed in place by the reflective coating 311.

At operation 35, as illustrated in FIG. 24 by intermediate structure/array 300D, array 313 is removed from the support 302.

With reference to FIG. 25, intermediate structure 350A comprises the array 313, which is flipped and placed in proximity to a device substrate 303, for example a printed circuit board (PCB) or other suitable substrate for inclusion in a final system or device. The device substrate 303 has device contacts 309pc2, 309pc1, 309r that correspond to respective UBMs 308pc2, 308pc1, 308r. The device contacts 309pc2, 309pc1, 309r are in a coplanar configuration relative to each other.

At operation 40, the array 313 of FIG. 26 is attached to the device substrate 303 to prepare LED device 250B of FIG. 20. The device contacts 309pc2, 309pc1, 309r and respective UBMs 308pc2, 308pc1, 308r are bonded or otherwise soldered. A bonding wire 312 electrically connected to the device substrate 303 is affixed to the wirebond pad 307 of each of the red LED die 201r.

FIG. 29 is a top plan view of array 313 of FIG. 25 prepared according to method 10 of FIG. 1 in conjunction with the specific sub-methods 1A.2 of FIG. 3 and 1B.3 of FIG. 6. As shown in FIG. 29, array 613 includes red LED die 601r including wirebond pad 607, first PC-LED die 601pc1, and second PC-LED die 601pc2, all of the die being held in place by reflective coating material 611.

In one or more embodiments, the LED die 601r, 601pc1, and 601pc2 are configured to emit different colors. In embodiments, the die 601r represents a first set of LED die each of a first die height and configured to emit a first/red light, the die 601pc1 represents a second set of LED die each of a second die height and configured to emit a second/green color light utilizing phosphor conversion; and the die 601pc2 represents a third set of LED die each of a third die height and configured to emit a third/blue color light utilizing phosphor conversion. As shown in cross-section of FIGS. 21-26, the plurality of LED die have a coplanar configuration and are spaced apart and retained by the reflective coating. In the embodiment of FIG. 29, the first set of LED die comprise a vertical configuration, and the second and third sets of LED die comprise a flip chip configuration and phosphor conversion.

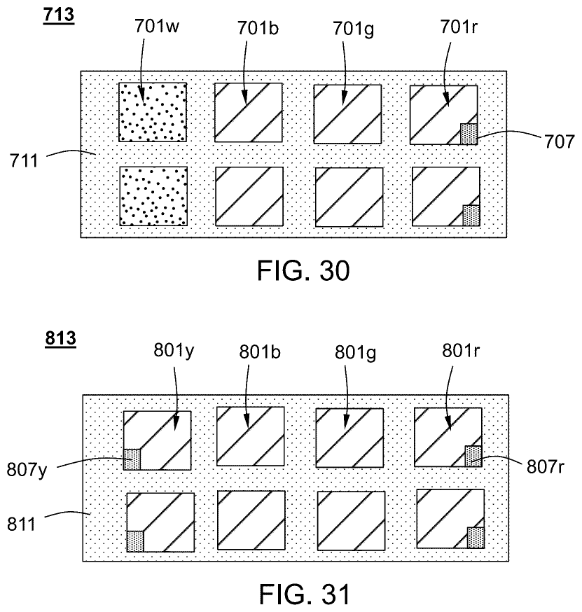

FIG. 30 is a top plan view of array prepared according to methods herein, including four types of die. As shown in FIG. 30, array 713 includes red LED die 701r including wirebond pad 707, green LED die 701g, blue LED die 701b, and PC-LED die 701w, all of the die being held in place by reflective coating material 711. In this way, the array and devices including the same include four colors, red, green, blue, and white.

FIG. 31 is a top plan view of array prepared according to methods herein, including four types of die. As shown in FIG. 31, array 813 includes red LED die 801r including wirebond pad 807, green LED die 801g, blue LED die 801b, and yellow die 801y including wirebond pad 807y, all of the die being held in place by reflective coating material 811. In this way, the array and devices including the same include four colors, red, green, blue, and yellow. The yellow die 801y is a vertical configuration analogous to the red die 801r with a different active layer in the semiconductor-containing structure.

In one or more embodiments, accordingly, the plurality of LED die further comprise a fourth set of LED die each of a fourth die height and configured to emit a fourth color light, and maintaining the plurality of LED die having the coplanar configuration and being spaced apart and retained by the reflective coating, wherein the fourth set of LED die comprise either a vertical configuration or a flip chip configuration; and optionally wherein the fourth color light is white or a yellow color.

### Applications

In one or more embodiments, a multicolor monolithic light-emitting diode (LED) array of any embodiment herein is attached to a device substrate, optionally wherein the device substrate includes a plurality of device contacts in a coplanar configuration, the device contacts corresponding respectively to the first, second, and third UBMs of the LED array; and a controller configured to control the plurality of pixels individually and/or in sets.

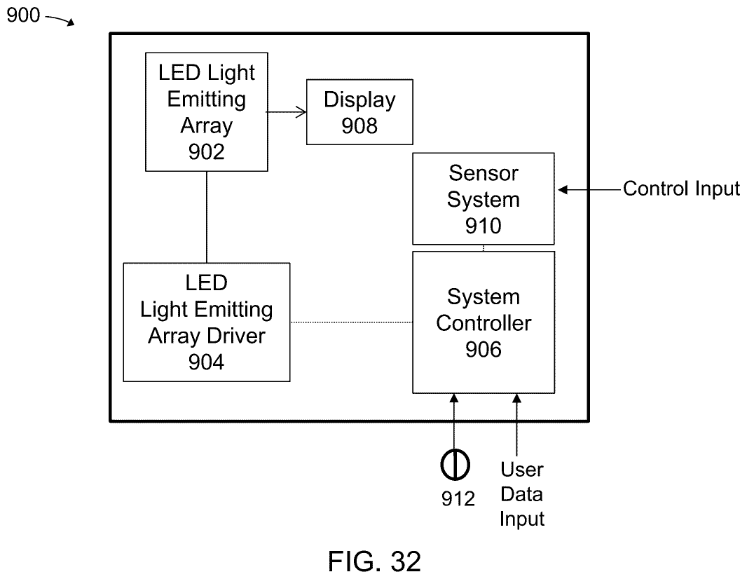

FIG. 32 schematically illustrates an exemplary LED system 900, e.g., a display system, utilizing LED arrays disclosed herein. The display system 900 comprises an LED light emitting array 902 and display 908 in electrical communication with an LED driver 904. The display system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

In operation, illumination from some or all of the pixels of the LED array in 902 may be adjusted—deactivated, operated at full intensity, or operated at an intermediate intensity. Beam focus or steering of light emitted by the LED array in 902 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

### EMBODIMENTS

Various embodiments are listed below. It will be understood that the embodiments listed below may be combined with all aspects and other embodiments in accordance with the scope of the invention.

Embodiment (a). A multicolor monolithic light-emitting diode (LED) array comprising: multicolor pixels comprising a plurality of light emitting diode (LED) die including: a first set of LED die each of a first die height and configured to emit a first color light; a second set of LED die each of a second die height and configured to emit a second color light; a third set of LED die each of a third die height and configured to emit a third color light; and the first die height being substantially equal to the second die height and the third die height; and the plurality of LED die having a coplanar configuration and being spaced apart and retained by a reflective coating.

Embodiment (b). The LED array of embodiment (a), wherein the first set of LED die comprise a vertical configuration, and the second set of LED die comprise a flip chip configuration, and the third set of LED die comprise either a vertical configuration or a flip chip configuration.

Embodiment (c). The LED array of embodiment (a) or (b), wherein the vertical configuration includes a silicon substrate and the flip chip configuration includes a sapphire substrate.

Embodiment (d). The LED array of any one of embodiments (a) to (c), wherein the first set of LED die comprise a vertical thin film (VTF) configuration, and the second set of LED die comprise a thin film flip chip configuration (TFFC), and the third set of LED die comprise either a VTF configuration or a TFFC configuration.

Embodiment (e). The LED array of any one of embodiments (a) to (d), wherein one or more of the first, second, and third sets of LED die further comprises a wavelength converting material, and optionally, wherein the wavelength converting material comprises a ceramic phosphor plate or a phosphor in silicone, and optionally wherein the wavelength converting material further comprises a transparent cover layer.

Embodiment (f). The LED array of any one of embodiments (a) to (e), wherein the first set of LED die comprise a phosphide light emitting layer, and the second and third sets of LED die comprise a nitride light emitting layer, optionally wherein the phosphide light emitting layer comprises AlInGaP, and the nitride light emitting layer comprises GaN or InGaN.

Embodiment (g). The LED array of any one of embodiments (a) to (f), wherein the first set of LED die each further comprise a bonding wire affixed to a wirebond pad of the first LED die while maintaining the coplanar configuration among the first, second, and third sets of LED die, and optionally the first set of LED die each further comprise a current spreading layer electrically coupled to the wirebond pad.

Embodiment (h). The LED array of any one of embodiments (a) to (g), wherein the first color light, the second color light, and the third color light all differ from each other, optionally wherein the first color light is a red light, the second color light is a green light, and the third color light is a blue light.

Embodiment (i). The LED array of any one of embodiments (a) to (h), wherein the plurality of LED die further comprise a fourth set of LED die each of a fourth die height and configured to emit a fourth color light, and maintaining the plurality of LED die having the coplanar configuration and being spaced apart and retained by the reflective coating, wherein the fourth set of LED die comprise either a vertical configuration or a flip chip configuration.

Embodiment (j). The LED array of embodiment (i), wherein the fourth color light is white or a yellow color.

Embodiment (k). The LED array of any one of embodiments (a) to (j) further including a layer of light absorbing material partially separating or separating the plurality of LED die, optionally the light absorbing material comprising of one or more of silicone, carbon particles, or a metal material.

Embodiment (l). The LED array of any one of embodiments (a) to (k), wherein the first die height, the second die height and the third die height have dimensions within 10 micrometers of each other, preferably 5 micrometers of each other.

Embodiment (m). The LED array of any one of embodiments (a) to (l), wherein: the first set of LED die each include a first semiconductor-containing structure of a first semiconductor height and a first under bump metallization (UBM) of a first UBM height; the second set of LED die each include a second semiconductor-containing structure of a second semiconductor height and a second under bump metallization (UBM) of a second UBM height; and a third set of LED die each include a third semiconductor-containing structure of a third semiconductor height and a third under bump metallization (UBM) of a third UBM height, wherein the first semiconductor-containing structure height is greater than the second semiconductor-containing structure height and/or the third semiconductor-containing structure height, and the first UBM height is less than the second UBM height and/or the third UBM height.

Embodiment (n). The LED array of embodiment (m), wherein the second semiconductor-containing structure height and third semiconductor-containing structure height have dimensions within 10 micrometers of each other, preferably 5 micrometers of each other.

Embodiment (o). The LED array of any one of embodiments (a) to (n), wherein the first, second, and third UBMs comprise one or more of: copper (Cu), nickel (Ni), aluminum (Al), gold (Au), and gold tin (AuSn), and/or the reflective coating comprises a reflective material comprising one or more of: silicone, silicon dioxide (SiO₂), titanium oxide (TiO₂), zirconium oxide (ZrO₂), and aluminum oxide (Al₂O₃), and/or the reflective coating has a reflectance in a range of from 80% to 99%.

Embodiment (p). A light-emitting diode (LED) system comprising: the multicolor monolithic light-emitting diode (LED) array of any one of embodiments (a) to (o) attached to a device substrate, optionally wherein the device substrate includes a plurality of device contacts in a coplanar configuration, the device contacts corresponding respectively to the first, second, and third UBMs of the LED array; and a controller configured to control the plurality of pixels individually and/or in sets.

Embodiment (q). A method for making a multicolor monolithic light-emitting diode (LED) array, the method comprising: assembling on a support in a spaced apart configuration a plurality of light emitting diode (LED) die including: a first set of LED die each of a first die height and configured to emit a first color; a second set of LED die each of a second die height and configured to emit a second color light; and a third set of LED die each of a third die height and configured to emit a third color light; disposing a reflective material on the plurality of LED die that retains the plurality of LED die in the spaced apart configuration; planarizing the reflective material such that the first die height is substantially equal to the second die height and the third die height and the plurality of LED die have a coplanar configuration; and removing the support thereby preparing the multicolor array.

Embodiment (r). The method of embodiment (q), wherein the first set of LED die comprise a vertical configuration, and the second set of LED die comprise a flip chip configuration, and the third set of LED die comprise either a vertical configuration or a flip chip configuration.

Embodiment(s). The method of embodiment (r), wherein the vertical configuration includes a silicon substrate and the flip chip configuration includes a sapphire substrate.

Embodiment (t). The method of embodiment (r) or(s), wherein the first set of LED die comprise a vertical thin film (VTF) configuration, and the second set of LED die comprise a thin film flip chip configuration (TFFC), and the third set of LED die comprise either a VTF configuration or a TFFC configuration.

Embodiment (u). The method of any one of embodiments (q) to (t) comprising planarizing the reflective material to expose backside surfaces of respective under bump metallizations (UBMs) of the first, second, and third sets of LED die.

Embodiment (v). The method of any one of embodiments (q) to (t) comprising planarizing topside surfaces of the first, second, and third sets of LED die.

Embodiment (w). The method of any one of embodiments (q) to (v) further comprising affixing a bonding wire to a wirebond pad of each of the first LED die prior to assembling on the support.

Embodiment (x). The method of any one of embodiments (q) to (w), wherein the first die height, the second die height and the third die height are within 5 micrometers of each other.

Embodiment (y). The method of any one of embodiments (q) to (x) further comprising preparing differing heights of the respective UBMs prior to assembling on the support to compensate for varying heights of respective semiconductor-containing structures of the LED die to maintain the coplanar configuration.

Embodiment (z). The method of any one of embodiments (q) to (y) further comprising grinding the second and the third sets of LED die prior to assembling on the support, optionally grinding the second and the third sets of LED die to a height in a range of greater than or equal to 45 micrometers to less than or equal to 120 micrometers.

Embodiment (aa). The method of any one of embodiments (q) to (z), wherein the plurality of LED die further comprise a fourth set of LED die each of a fourth die height and configured to emit a fourth color light and maintaining the plurality of LED die being spaced apart and retained by the reflective coating, and having the coplanar configuration.

Embodiment (bb). A method for operating a display, the method comprising: determining an image to present on the display; driving the plurality of pixels of the LED system of embodiment (p) to provide the image; and controlling individual and/or sets of the plurality of pixels.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A multicolor monolithic light-emitting diode (LED) array comprising: multicolor pixels comprising a plurality of light emitting diode (LED) die including:
a first set of LED die each of a first die height and configured to emit a first color light;
a second set of LED die each of a second die height and configured to emit a second color light;
a third set of LED die each of a third die height and configured to emit a third color light; and
the first die height being substantially equal to the second die height and the third die height; and
the plurality of LED die having a coplanar configuration and being spaced apart and retained by a reflective coating.

2. The LED array of claim 1, wherein the first set of LED die comprise a vertical configuration, and the second set of LED die comprise a flip chip configuration, and the third set of LED die comprise either a vertical configuration or a flip chip configuration.

3. The LED array of claim 2, wherein the vertical configuration includes a silicon substrate and the flip chip configuration includes a sapphire substrate.

4. The LED array of claim 2, wherein the first set of LED die comprise a vertical thin film (VTF) configuration, and the second set of LED die comprise a thin film flip chip configuration (TFFC), and the third set of LED die comprise either a VTF configuration or a TFFC configuration.

5. The LED array of claim 1, wherein one or more of the first, second, and third sets of LED die further comprises a wavelength converting material, and optionally, wherein the wavelength converting material comprises a ceramic phosphor plate or a phosphor in silicone, and optionally wherein the wavelength converting material further comprises a transparent cover layer.

6. The LED array of claim 1, wherein the first set of LED die comprise a phosphide light emitting layer, and the second and third sets of LED die comprise a nitride light emitting layer, optionally wherein the phosphide light emitting layer comprises AlInGaP, and the nitride light emitting layer comprises GaN or InGaN.

7. The LED array of claim 1, wherein the first set of LED die each further comprise a bonding wire affixed to a wirebond pad of the first LED die while maintaining the coplanar configuration among the first, second, and third sets of LED die, and optionally the first set of LED die each further comprise a current spreading layer electrically coupled to the wirebond pad.

8. The LED array of claim 1, wherein the first color light, the second color light, and the third color light all differ from each other, optionally wherein the first color light is a red light, the second color light is a green light, and the third color light is a blue light.

9. The LED array of claim 1, wherein the plurality of LED die further comprise a fourth set of LED die each of a fourth die height and configured to emit a fourth color light, and maintaining the plurality of LED die having the coplanar configuration and being spaced apart and retained by the reflective coating, wherein the fourth set of LED die comprise either a vertical configuration or a flip chip configuration; and optionally wherein the fourth color light is white or a yellow color.

10. The LED array of claim 1, wherein the first die height, the second die height and the third die height have dimensions within 10 micrometers of each other.

11. The LED array of claim 1, wherein:
the first set of LED die each include a first semiconductor-containing structure of a first semiconductor height and a first under bump metallization (UBM) of a first UBM height;
the second set of LED die each include a second semiconductor-containing structure of a second semiconductor height and a second under bump metallization (UBM) of a second UBM height; and
a third set of LED die each include a third semiconductor-containing structure of a third semiconductor height and a third under bump metallization (UBM) of a third UBM height,
wherein the first semiconductor-containing structure height is greater than the second semiconductor-containing structure height and/or the third semiconductor-containing structure height, and the first UBM height is less than the second UBM height and/or the third UBM height.

12. The LED array of claim 1, wherein the first, second, and third UBMs comprise one or more of: copper (Cu), nickel (Ni), aluminum (Al), gold (Au), and gold tin (AuSn), and/or the reflective coating comprises a reflective material comprising one or more of: silicone, silicon dioxide (SiO₂), titanium oxide (TiO₂), zirconium oxide (ZrO₂), and aluminum oxide (Al₂O₃), and/or the reflective coating has a reflectance in a range of from 80% to 99%.

13. A light-emitting diode (LED) system comprising: the multicolor monolithic light-emitting diode (LED) array of claim 1 attached to a device substrate, optionally wherein the device substrate includes a plurality of device contacts in a coplanar configuration, the device contacts corresponding respectively to the first, second, and third UBMs of the LED array; and a controller configured to control the plurality of pixels individually and/or in sets.

14. A method for making a multicolor monolithic light-emitting diode (LED) array, the method comprising:
assembling on a support in a spaced apart configuration a plurality of light emitting diode (LED) die including:
a first set of LED die each of a first die height and configured to emit a first color;
a second set of LED die each of a second die height and configured to emit a second color light; and
a third set of LED die each of a third die height and configured to emit a third color light;
disposing a reflective coating material on the plurality of LED die that retains the plurality of LED die in the spaced apart configuration;
planarizing the reflective coating material such that the first die height is substantially equal to the second die height and the third die height and the plurality of LED die have a coplanar configuration; and
removing the support thereby preparing the multicolor array.

15. The method of claim 14 comprising planarizing the reflective coating material to expose backside surfaces of respective under bump metallizations (UBMs) of the first, second, and third sets of LED die.

16. The method of claim 14 comprising planarizing topside surfaces of the first, second, and third sets of LED die.

17. The method of claim 15 further comprising affixing a bonding wire to a wirebond pad of each of the first LED die prior to assembling on the support.

18. The method of claim 16 further comprising preparing differing heights of the respective UBMs prior to assembling on the support to compensate for varying heights of respective semiconductor-containing structures of the LED die to maintain the coplanar configuration.

19. The method of claim 14 further comprising grinding the second and the third sets of LED die prior to assembling on the support, optionally grinding the second and the third sets of LED die to a height in a range of greater than or equal to 45 micrometers to less than or equal to 120 micrometers.

20. The method of claim 14, wherein the plurality of LED die further comprise a fourth set of LED die each of a fourth die height and configured to emit a fourth color light and maintaining the plurality of LED die being spaced apart and retained by the reflective coating, and having the coplanar configuration.
